(19) United States
(12) Patent Application Publication
(10) Pub. No.: US 2020/0241059 A1
(43) Pub. Date: Jul. 30, 2020

(54) DEVICE AND METHOD FOR DETERMINING A TEMPERATURE-DEPENDENT IMPEDANCE CURVE ALONG AN ELECTRICAL CONDUCTOR

(71) Applicant: LEONI KABEL GMBH, Roth (DE)

(72) Inventor: SERGEY INTELMAN, Nuernberg (DE)

(21) Appl. No.: 16/637,301

(22) PCT Filed: Jul. 31, 2018
(86) PCT No.: PCT/EP2018/070725

§ 371 Date: Mar. 31, 2020

(30) Foreign Application Priority Data
Aug. 10, 2017 (DE) 10 2017 213 931.5

(51) Int. Cl. G01R 27/16; G01R 27/04; G01R 23/163

(52) U.S. Cl. CPC G01R 27/16; G01R 23/163; G01R 27/04

(57) ABSTRACT

The invention relates to a device for determining a temperature-dependent impedance curve along an electrical conductor, which device has a signal generator unit, which is arranged and designed to generate a multi-frequency electrical signal, which passes through an electrical conductor. The device also has a frequency spectrum sensing unit, which is arranged and designed to sense a frequency spectrum of a multi-frequency electrical signal leaving the conductor at least in a predefined frequency range. The device also has a frequency spectrum difference determination unit, which is arranged and designed to determine a frequency difference between the sensed frequency spectrum and a predefined frequency spectrum. The device also has a frequency difference conversion unit, which is designed and arranged to determine an amplitude curve of the determined frequency difference along the electrical conductor.

### RELATED APPLICATIONS

This application filed under 35 U.S.C § 371 is a national phase application of International Application Serial Number PCT/EP2018/070725 filed Jul. 31, 2018, which claims the benefit of German Application No. 10 2017 213 931.5 filed Aug. 10, 2017, the entirety of which are incorporated by herein by reference.

### TECHNICAL FIELD

The invention relates to a device and a method for determining a temperature-dependent impedance curve along an electrical conductor.

### BACKGROUND OF THE INVENTION

Electrical conductors may get hot due to electric currents, for example, which flow through the electrical conductor. The properties of the conductors, for example an impedance of the conductors, can change due to this.

In the technical field of electromobility, for example, charging cables are used to charge batteries of electric vehicles, through which cables there are flowing currents with considerable current intensity in part during a charging operation. A consequence is heating of the charging cable in sections or completely, accompanied by a significant increase in the line impedance in some cases.

If the quantitative as well as the qualitative effects of heating of a conductor on its resistance properties are to be determined, a measuring device and/or a measuring method are required.

A known method for determining cable damage is time domain reflectrometry, or TDR for short. In this, an electrical signal, preferably a pulsed signal, is supplied to an electrical cable. If the electrical cable is cut at one point, the signal is reflected at this point. A position of the separation point can be determined by measuring the propagation time of the reflected signal. If the cable is not severed but is damaged at one point, so that an impedance of the cable is increased in the region of the damage, the increased impedance causes a partial reflection of the signal. By measuring a propagation time of the partly reflected signal, a position of the increased impedance can be determined and by means of the amplitude of the reflected a relation of the increased impedance to the surrounding cable impedance can be determined.

Another known method for determining cable damage is frequency domain reflectrometry, or FDR for short. Here signals of different frequencies are supplied to a cable and the frequency spectrum of the reflected signals is determined. The frequency spectra determined are further converted by means of a Fourier transform to a signal representation. The position of an increased impedance and/or of a cable separation can be rendered visible by an impedance curve along the cable length. When determining the impedance curve both the phase information of the reflected signals and the amount of the reflected signals can be taken into account.

A disadvantage of the known methods (FDR, TDR) is that the measuring devices or measuring set-ups required for these are expensive, technically complex and not very portable due to their size and their weight. This is due primarily to the highly sensitive and broadband HF components for detecting the reflected signals, such as analog-digital converters or amplifiers, for example.

The application areas of known measuring devices are therefore limited to laboratories or extremely cost-intensive application fields in which the high costs of the measuring device recede into the background (e.g. submarine cables, oil pipelines). For less cost-intensive application areas, for example checking shorter cables with a length of e.g. 10 m, the use of the known devices and methods makes no sense for economic reasons and is therefore uncommon.

There is thus a need for an improved, in particular more cost-effective, device and an improved, in particular more cost-effective, method for determining a temperature-dependent impedance curve along an electrical conductor.

### SUMMARY OF THE INVENTION

A device for determining a temperature-dependent impedance curve along an electrical conductor has a signal generator unit. The signal generator unit is arranged and designed to generate a multi-frequency electrical signal, in particular a time-variant multi-frequency signal or a time-invariant noise signal, which passes through an electrical conductor. The device for determining a temperature-dependent impedance curve further has a frequency spectrum sensing unit. The frequency spectrum sensing unit is arranged and designed to sense a frequency spectrum of a multi-frequency electrical signal leaving the conductor at least in a predefined frequency range. The device for determining a temperature-dependent impedance curve further has a frequency spectrum difference determination unit. The frequency spectrum difference determination unit is arranged and designed to determine a frequency difference between the sensed frequency spectrum and a predefined frequency spectrum. The device for determining a temperature-dependent impedance curve further has a frequency difference conversion unit. The frequency difference conversion unit is arranged and designed to determine an amplitude curve/a time domain representation of the determined frequency difference along the electrical conductor.

By means of the time domain representation of the determined frequency difference, an impedance curve or deviations from a TARGET impedance curve along the electrical conductor can be deduced. The time domain representation of the determined frequency difference corresponds to the impedance curve or to the deviation from the TARGET impedance curve along the electrical conductor.

An advantage of the device is that by determining the frequency difference between the sensed frequency spectrum and a predefined frequency spectrum, both a point impedance variation and a uniform impedance variation of the entire conductor can be identified and quantified. If the entire conductor is heated uniformly by a temperature, the impedance of the entire conductor likewise increases uniformly. No signal reflection thus takes place at a conductor section with an increased impedance relative to its conductor environment. However, the frequency spectrum reflected by the conductor changes such that the frequency difference determined between the sensed frequency spectrum and the predefined frequency spectrum following the conversion of an amplitude representation/time domain representation shows a uniformly increased impedance on account of the increased temperature as a constant linear shift of the signal amplitude.

If the predefined frequency spectrum is, for example, the frequency spectrum of the electrical conductor under predefined conditions, in particular in the case of a predefined conductor temperature, then with the constant shift of the determined signal amplitude, with the aid of Ohm's law, the change in line impedance and indirectly, e.g. by multiplication by a conductor-specific temperature coefficient, the rise in the conductor temperature can be deduced.

Furthermore, the device can comprise an amplifier unit, which is arranged and designed to amplify the multi-frequency electrical signal.

An advantage of amplifying the signal, in particular before the passage through the electrical conductor, is that signal losses due to the attenuation of the conductor in relation to the signal strength are reduced.

The multi-frequency signal generated can be in particular a noise signal, for example a continuous white or Gaussian noise signal. The noise signal can have a bandwidth, for example, of up to 2 GHz. In another embodiment the multi-frequency signal generated can be a time-variant multi-frequency signal, in particular a frequency sweep.

In a specific embodiment, for determining a temperature-dependent impedance curve along an electrical conductor, the device comprises a directional coupler, which is connected electrically conductively to a conductor end of the electrical conductor and is arranged and designed to introduce the multi-frequency electrical signal generated by the signal generator unit into the electrical conductor.

Here the electrical conductor preferably has an open conductor end, which reflects at least a portion of the multi-frequency signal introduced into the electrical conductor. The directional coupler is further arranged and designed to lead out the signal reflected by the conductor, in particular by the open conductor end, as the multi-frequency electrical signal leaving the electrical conductor.

An advantage of using a directional coupler is that a reflected multi-frequency signal/frequency spectrum can be sensed by the frequency spectrum sensing unit. In other embodiments a multi-frequency signal/frequency spectrum passing once through the line can be sensed at a line end. Here the reflected signal/frequency spectrum can be determined by subtraction of the signal/frequency spectrum introduced into the line with the signal/frequency spectrum passing through the line. Alternatively the multi-frequency signal/frequency spectrum passing once through the line can be supplied without prior subtraction with the signal/frequency spectrum introduced into the line to the frequency spectrum sensing unit, wherein an adaptation analogous to this of the predefined frequency spectrum is a prerequisite. The selection/determination of the predefined frequency spectrum is described in greater detail below.

In one variant the frequency spectrum sensing unit and/or the signal generator unit is a software-defined radio, or SDR for short. The frequency spectrum sensing unit can have a frequency sensing range from 25 to 1750 MHz. Furthermore, the frequency spectrum sensing unit can have a software-based signal processing. In one embodiment the frequency spectrum sensing unit can have a USB (universal serial bus) port.

A software-defined radio, SDR for short, is a device that has at least one high-frequency receiver and manages at least a portion of the signal processing through a computer-aided method. An SDR can also have a signal generator unit, which is suitable to generate a multi-frequency signal, in particular a noise signal. Variants of an SDR that have a signal generator unit for generating a time-variant multi-frequency signal are likewise possible. SDRs are characterised by their partly small size, their low weight and their low-cost availability on the market. Furthermore, SDRs in measuring technology, for example, can have normal 50 Ohm SMA connectors and/or a USB port. SDRs are therefore especially suited to non-stationary use and/or to interact with computer devices, in particular portable ones.

An advantage of using an SDR, apart from the possible low weight/small size and favourable availability on the market, consists in the fact that SDRs are sometimes freely configurable, in particular freely programmable and permit user-individual adaptation, for example of the signal generated. SDRs are thus suitable as device constituents for a device for determining a temperature-dependent impedance curve along a plurality of different conductors.

The frequency spectrum sensing unit can be arranged and designed to determine at least phase information and/or a signal propagation time of the multi-frequency electrical signal leaving the conductor. However, this is explicitly not provided in all embodiments. If the signal generator generates a continuous noise signal, for example, the frequency spectrum sensing unit can be designed to sense the frequency spectrum of the multi-frequency electrical signal leaving the conductor at least in a predefined frequency range without determining phase information and/or a signal propagation time.

In one embodiment the predefined frequency spectrum is a frequency spectrum, sensed by the frequency spectrum sensing unit, of the multi-frequency signal leaving the electrical conductor or an electrical reference conductor under predefined (environmental) conditions, wherein the signal supplied to the conductor or reference conductor is identical to the multi-frequency signal that is supplied to the electrical conductor for determining the impedance curve. The predefined (environmental) conditions are in particular a freedom from damage and/or a constant temperature, preferably of 20 degrees Celsius, of the entire electrical conductor or of the entire reference conductor.

An advantage of determining/defining the predefined frequency spectrum by sensing the frequency spectrum of the multi-frequency signal leaving the electrical conductor or reference conductor under predefined (environmental) conditions is that the determined frequency difference from the predefined frequency spectrum represents a deviation from a predefined state of the electrical conductor. Thus following the conversion of the frequency difference to a time domain representation, no signal/no impedance is represented but only a signal change/an impedance change.

An advantage of determining the predefined frequency spectrum by means of a reference conductor is that in the case of a plurality of identically produced electrical conductors with identical properties, for example, the determination effort for the predefined frequency spectrum can be reduced if a conductor selected from the plurality as reference conductor is used to be representative of the plurality of identical conductors.

In one variant the frequency difference conversion unit is designed and arranged to determine the amplitude curve/the time domain representation along the electrical conductor by an inverse

Fourier transform, in particular by a fast inverse Fourier transform, of the previously determined frequency difference.

An advantage here is that the fast inverse Fourier transform is suitable for the resource-efficient implementation of computer-aided conversion methods.

In those embodiments of the device in which the frequency spectrum sensing unit determines phase information and/or a signal propagation time of the multi-frequency electrical signal leaving the conductor, the frequency difference conversion unit can be arranged and designed to use the phase information determined by the frequency spectrum sensing unit for propagation time or conductor length referencing of the amplitude curve/the time domain representation.

In one variant the electrical conductor can be enclosed in particular by a dielectric with temperature-variant properties. In particular, a dielectric constant of the dielectric enclosing the conductor can change with increasing or decreasing temperature. For example, the conductor can be a coaxial cable with a PVC dielectric. The temperature-variant properties of the dielectric can promote an impedance increase of the conductor in consequence of a local or constant heating of the conductor, so that heating of the conductor can be identified/determined more easily/simply/clearly by the device described here.

A method for determining a temperature-dependent impedance curve along an electrical conductor comprises the steps:
generation of a multi-frequency electrical signal, in particular a time-variant multi-frequency electrical signal or a time-invariant electrical noise signal, which passes through an electrical conductor,
sensing of a frequency spectrum, at least in a predefined frequency range, of a multi-frequency electrical signal leaving the conductor,
determination of a frequency difference between the sensed frequency spectrum and a predefined frequency spectrum, and
determination of an amplitude curve of the frequency difference along the electrical conductor.

If the power of the multi-frequency electrical signal is constant, the amplitude curve can be transferred to an impedance curve.

The method can further comprise at least one of the steps:
amplification of the multi-frequency electrical signal
introduction of the multi-frequency electrical signal into the electrical conductor
leading out of the multi-frequency electrical signal reflected by the electrical conductor as the signal leaving the conductor, wherein the electrical conductor has in particular an open conductor end, which reflects at least a portion of the signal introduced into the electrical conductor.

Other features, properties, advantages and possible modifications will become clear to a person skilled in the art by means of the following description, in which reference is made to the enclosed drawings.

DETAILED DESCRIPTION OF THE DRAWINGS

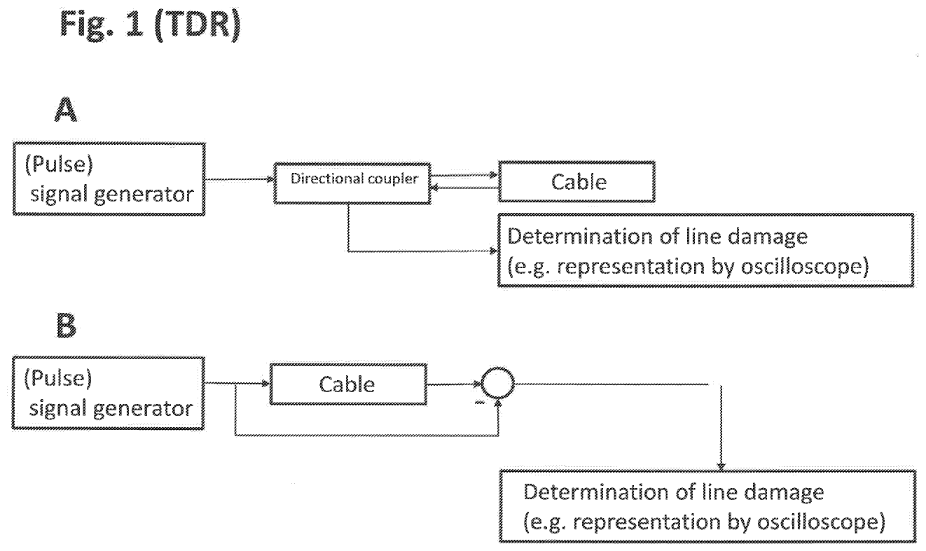

FIG. 1A-1B show schematically a measurement arrangement for time domain reflectrometry.

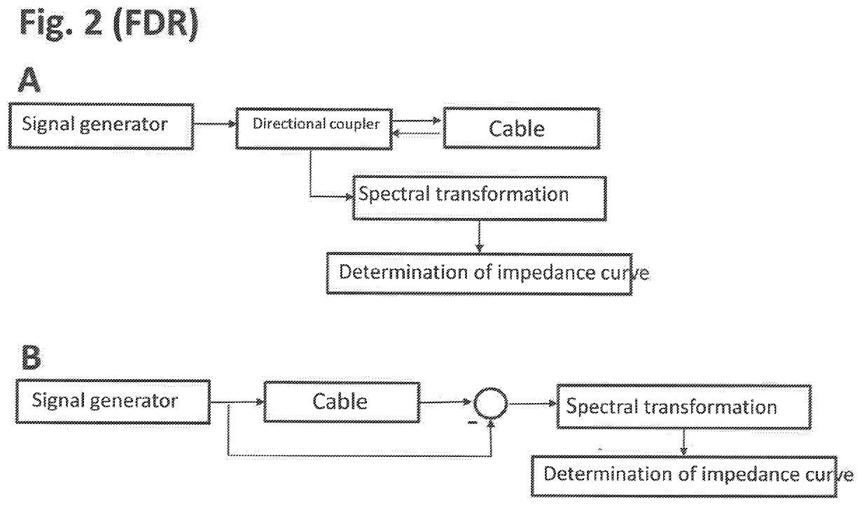

FIG. 2A-2B show schematically a measurement arrangement for frequency domain reflectrometry.

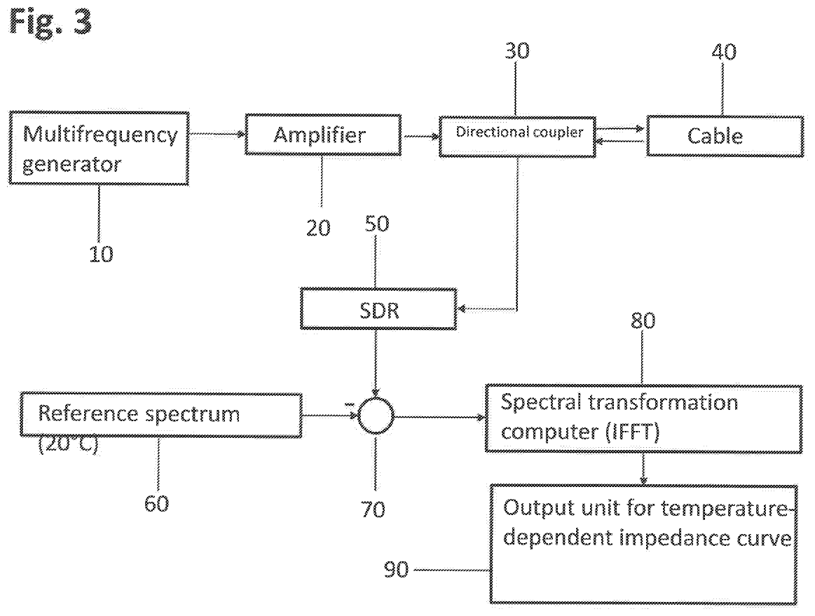

FIG. 3 shows schematically a possible embodiment of a device for determining a temperature-dependent impedance curve along an electrical conductor.

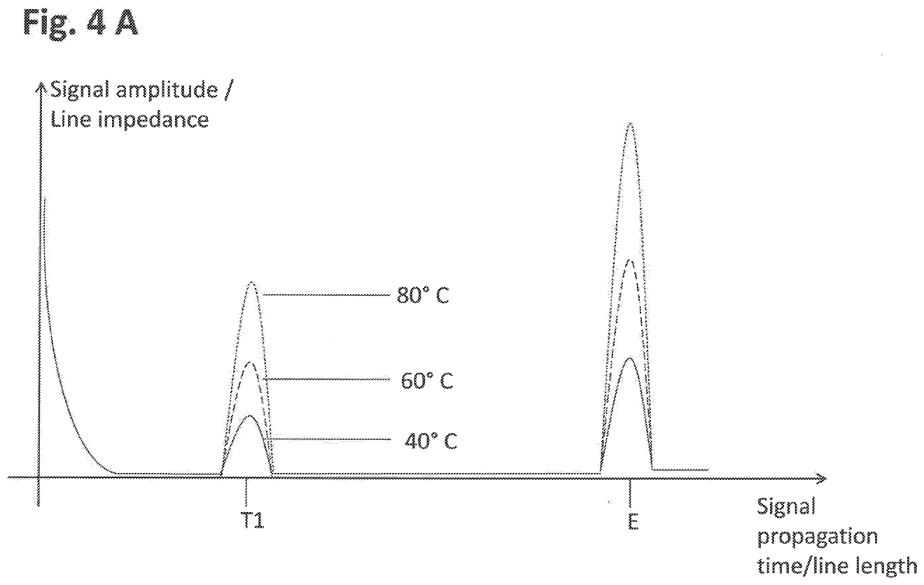

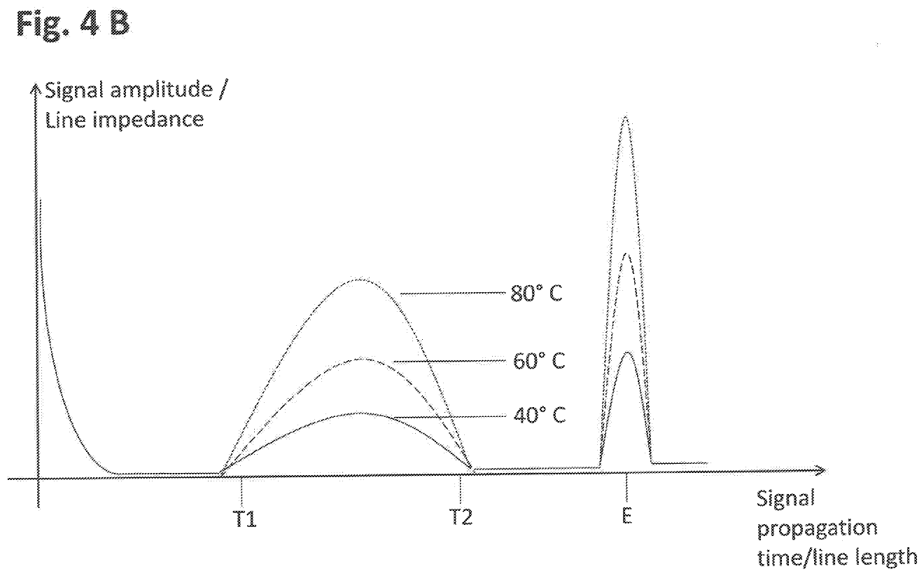

FIG. 4A-4B show schematically the effects of increasing heating of the electrical conductor on the signal amplitude and the curve of the conductor impedance.

### DETAILED DESCRIPTION

FIG. 1 shows schematically the construction of a measuring arrangement for time domain reflectrometry.

In the variant A shown in FIG. 1, a (pulse) signal is supplied via a directional coupler to a cable. The cable is connected electrically conductively to the directional coupler only at one end, while an opposite cable end is open or electrically isolated.

A (pulse) signal reflected by the cable end is led out by the directional coupler and supplied to an evaluation or representation means, for example with an oscilloscope. The cable length can be deduced by determining the propagation time of the signal.

If the cable is cut at one point, the (pulse) signal is reflected at this point. A position of the separation point can be determined by a propagation time measurement of the reflected signal.

If the cable is not cut, but is damaged at a point, so that an impedance of the line is increased at a point or in a locally delimited area, the increased impedance causes a partial reflection of the (pulse) signal. By means of the propagation time measurement of the partially reflected (pulse) signal there can be determined a position of the increased impedance, and by means of the amplitude of the partially reflected (pulse) signal, a relation of the increased impedance to the line impedance surrounding the damage.

In contrast to variant A, in the variant B shown in FIG. 1 the (pulse) signal is conducted completely through a cable electrically contacted at two cable ends. The signal which leaves the cable is subtracted from the signal which is supplied to the cable and the difference signal determined in this way is evaluated or represented analogously to variant A.

FIG. 2 shows schematically the construction of a measuring arrangement for frequency domain reflectrometry or vector frequency domain reflectrometry.

In the variant A shown in FIG. 2, a multi-frequency signal is supplied to a cable via a directional coupler. The cable is connected electrically conductively to the directional coupler only at one end, while an opposite cable end is open or electrically isolated.

The frequency spectrum of the reflected multi-frequency signal is sensed and led out by the directional coupler.

A transformation of the sensed frequency spectrum into an amplitude representation/time domain representation, for example with an oscilloscope, shows the curve of a voltage drop/an impedance along the cable.

In the variant B shown in FIG. 2, the multi-frequency signal, in contrast to variant A of FIG. 2 and by analogy with variant B in FIG. 1, is conducted completely through a cable electrically contacted at two cable ends. The frequency spectrum of the signal leaving the cable is subtracted from the frequency spectrum of the signal supplied to the cable and the difference spectrum determined thus is evaluated or represented analogously to variant A.

FIG. 3 shows by way of example and schematically an embodiment of a device for determining a temperature-dependent impedance curve along an electrical cable.

A multi-frequency generator 10 produces a multi-frequency signal. The multi-frequency signal is amplified by an amplifier 20 and then supplied to a directional coupler 30. In the exemplary embodiment shown in FIG. 3, the multi-frequency signal is a time-invariant noise signal, but embodiments with a time-variant multi-frequency signal, for example with a frequency sweep, are also possible.

The directional coupler 30 conducts the amplified multi-frequency signal to a cable 40, wherein one end of the cable 40 is connected electrically conductively to the directional coupler 30 and another cable end is open or electrically isolated.

The amplified multi-frequency signal is reflected by the cable 40, in particular by the open or isolated cable end. The reflected amplified multi-frequency signal is supplied by the directional coupler 30 to a software-defined radio, SDR for short, 50. The SDR 50 determines a frequency spectrum of the reflected amplified multi-frequency signal.

In a further development (not shown) the multi-frequency signal is generated by the SDR 50 and supplied to the amplifier 20. The SDR thus replaces the multi-frequency generator 10 in this further development, wherein this is not in conflict with the function of the SDR 50 in the device shown in FIG. 3. The SDR 50 thus makes it possible to save on device constituents in this further development. A (construction) size of the device shown can thus be reduced and the costs of implementing the device shown can be reduced by this.

In embodiments of the device (not shown) which provide a multi-frequency signal in the form of a frequency sweep, for example, the SDR 50 can also determine phase information of the reflected amplified multi-frequency signal.

The frequency spectrum of the reflected amplified multi-frequency signal determined by the SDR 50 is further supplied to a frequency spectrum difference determination unit 70. The frequency spectrum difference determination unit 70 determines a frequency difference between the frequency spectrum of the reflected amplified multi-frequency signal and a reference spectrum 60.

The reference spectrum 60 has been defined previously by a determination of a reflected amplified multi-frequency signal of a reference cable (not shown). To this end a signal identical to the amplified multi-frequency signal, preferably a signal generated by the same arrangement of multi-frequency generator 10, amplifier 20 and directional coupler 30, is supplied to the reference cable and by analogy with the arrangement shown in FIG. 3 a frequency spectrum/reference spectrum is determined. The reference cable is a cable identical or at least identical in properties to the cable 40 that is free of damage and has a uniform/constant temperature of 20° C. By analogy with the arrangement shown in FIG. 3, one cable end of the reference cable is open or electrically isolated during determination of the reflected electrical multi-frequency signal.

In other words, in the device shown in FIG. 3, the frequency spectrum actually determined by the SDR 50 of the reflected amplified multi-frequency signal is compared with a predefined “target spectrum”.

The frequency difference determined by the frequency spectrum difference determination unit 70 is supplied to a spectral transformation computer 80. This transforms the frequency difference using an inverse fast Fourier transform, IFFT for short, into an amplitude representation/time domain representation.

In the exemplary embodiment shown the spectral transformation computer 80 is a portable computer device. The IFFT is performed by means of known algorithms and is not to be described in greater detail at this point.

In one embodiment of the device (not shown), the spectral transformation computer 80 can additionally use also phase information determined by the SDR 50, for example of a frequency sweep, to determine the amplitude representation/time domain representation. This makes a line-length- or propagation-time-referenced amplitude representation possible.

The determined, in particular line-length- and/or propagation-time-referenced amplitude representation is supplied to an output unit for the temperature-dependent impedance curve 90 and is output by this.

In one variant the frequency spectrum difference determination unit 70, the spectral transformation computer 80 and the output unit 90 can be realised jointly by a portable computer device with screen, for example by a standard (portable) computer. The reference spectrum 60 can be stored by the computer device and/or provided by this.

FIG. 4A shows examples of temperature-dependent impedance curves output by the output unit 90. Here the signal propagation time and/or the cable length is plotted on the abscissa and the signal amplitude and/or the cable impedance on the ordinate in a coordinate system, wherein the signal propagation time and the cable length as well as signal amplitude or the cable impedance are each transferable into one another by the multiplication of constants, if the signal propagation velocity and the power of the multi-frequency signal are at least substantially constant.

If a first point T1 or a section of the cable 40 is heated, a local increase in the cable impedance takes place due to the heating. The rise in the cable impedance changes the line properties of the overall cable such that the frequency spectrum determined by the SDR 50 differs from the reference spectrum 60. If the frequency difference between the determined frequency spectrum and reference spectrum 60 is converted by means of an IFFT into an amplitude representation/time domain representation, then at the point T1 (if the abscissa is standardised to a cable length) a rise in the signal amplitude or cable impedance appears. The rise increases as the temperature rises. A change in the signal amplitude and the cable impedance over a period and/or different usage states of the cable can be used to discern a change in impedance caused by temperature and a change in impedance caused by damage.

Analogous to the increase in signal amplitude or cable impedance at the first point T1, a change in the signal amplitude or cable impedance represented at the open cable end E takes place due to the change in line properties of the overall cable. The cable impedance represented at the line end E does not correspond to the actual cable impedance at the cable end, as for a correct representation an unlimited frequency spectrum would have had to be sensed. The signal amplitude or line impedance actually represented at the cable end E changes with a rising temperature, however, by analogy with the signal amplitude or cable impedance at the heated first point T1 and can thus be used additionally to determine the temperature rise.

In addition, with a known cable length the abscissa can be standardised by the recognisable (variable) cable impedance at the open cable end E. In other words, the abscissa point with the recognisable (variable) impedance corresponds to the cable end E, so that an (at least approximate) standardisation of the abscissa is possible with a known cable length (if no complete cable separation/damage is present). This is advantageous primarily in embodiments of the device/method without propagation time or phase information determination. The standardisation can be carried out in particular also with the measurement of the reference spectrum on the reference cable.

FIG. 4B shows the effects of an extension of the heating to a section of the cable between a first point T1 and a second point T2, wherein the maximum of the heating is attained between the first point T1 and the second point T2. As a result, there occurs in the amplitude representation/time domain representation a rise in the signal amplitude or the cable impedance that extends by analogy with the heating along the cable.

An advantage in this case consists in the fact that even a complete uniform heating of the cable is identifiable and quantifiable by a rise in/an offset of the/to the signal amplitude or the cable impedance.

It is understood that the exemplary embodiments explained above are not conclusive and do not restrict the subject matter disclosed here. In particular, it is obvious to the person skilled in the art that he can combine the features described with one another in any way and/or can omit various features without departing from the subject matter disclosed here.

1. A device for determining a temperature-dependent impedance curve along an electrical conductor, having:
a signal generator unit, which is arranged and designed to generate a multi-frequency electrical signal with constant power, which passes through an electrical conductor,
a frequency spectrum sensing unit, which is arranged and designed to sense a frequency spectrum of a multi-frequency electrical signal leaving the conductor at least in a predefined frequency range, wherein
the signal generator unit and the frequency spectrum sensing unit are jointly formed by a software-defined radio (SDR),
a frequency spectrum difference determination unit, which is arranged and designed to determine a frequency difference between the sensed frequency spectrum and a predefined frequency spectrum, and
a frequency difference conversion unit, which is arranged and designed to determine an amplitude representation in the time domain of the determined frequency difference along the electrical conductor.

2. Device according to claim 1, wherein the multi-frequency electrical signal is a noise signal, in particular a continuous white noise signal, or the multi-frequency electrical signal is a time-variant signal, in particular a frequency sweep.

3. Device according to claim 1, further having an amplifier unit, which is arranged and designed to amplify the multi-frequency electrical signal.

4. Device according to claim 1, further having
a directional coupler, which is connected electrically conductively to a conductor end of the electrical conductor and is arranged and designed
to introduce the multi-frequency electrical signal generated by the signal generator unit into the electrical conductor, and
to lead out a multi-frequency electrical signal reflected by the electrical conductor as the multi-frequency electrical signal leaving the electrical conductor, wherein
the electrical conductor has in particular one open conductor end, which reflects at least a portion of the signal introduced into the electrical conductor.

5. Device according to claim 1, wherein
the frequency spectrum sensing unit is arranged and designed to determine at least a phase information of the multi-frequency electrical signal leaving the conductor, and/or
the frequency spectrum sensing unit has a frequency sensing range from 25 to 1750 MHz, and/or
the frequency spectrum sensing unit has software-based signal processing, and/or
the frequency spectrum sensing unit has a USB port.

6. Device according to claim 1, wherein the predefined frequency spectrum is a frequency spectrum, sensed by the frequency spectrum sensing unit, of the electrical signal leaving the electrical conductor or an electrical reference conductor under predefined conditions, wherein the predefined conditions comprise in particular a freedom from damage and/or a constant temperature, preferably of 20 degrees Celsius, of the electrical conductor or the reference conductor.

7. Device according to claim 1, wherein the frequency difference conversion unit is arranged and designed to determine the amplitude curve along the electrical conductor using an inverse Fourier transform, in particular a fast inverse Fourier transform, of the frequency difference, and/or
the frequency difference conversion unit is further arranged and designed to use phase information for a propagation time or conductor length referencing of the amplitude curve.

8. Device according to claim 1, wherein the electrical conductor is enclosed by a dielectric with temperature-variant properties, in particular by a dielectric with a temperature-dependent dielectric constant.

9. Method for determining a temperature-dependent impedance curve along an electrical conductor with the steps:
generation of a multi-frequency electrical signal with constant output, which passes through an electrical conductor, with a software-defined radio (SDR),
sensing of a frequency spectrum, at least in a predefined frequency range, of a multi-frequency electrical signal leaving the conductor with the SDR,
determination of a frequency difference between the sensed frequency spectrum and a predefined frequency spectrum, and
determination of an amplitude representation in the time domain of the frequency difference along the electrical conductor.

10. Method according to claim 9, further comprising at least one of the steps:
amplification of the multi-frequency electrical signal
introduction of the multi-frequency electrical signal into the electrical conductor,
leading out of a multi-frequency electrical signal reflected by the electrical conductor as the multi-frequency signal leaving the conductor, wherein
the electrical conductor has in particular an open conductor end, which reflects at least a portion of the multi-frequency signal introduced into the electrical conductor.
